(19) United States
(12) Patent Application Publication
(10) Pub. No.: US 2025/0031486 A1
(43) Pub. Date: Jan. 23, 2025

(54) LIGHT-EMITTING DEVICE WITH QUANTUM DOTS AND MANUFACTURING METHOD THEREOF

(71) Applicant: QDLUX INC., Hsinchu City (TW)

(72) Inventors: Ching-Liang Yi, Hsinchu City (TW); Jung-Hua Chang, Hsinchu City (TW); Chen-Yang Huang, Hsinchu City (TW)

(21) Appl. No.: 18/367,273

(22) Filed: Sep. 12, 2023

(30) Foreign Application Priority Data
Jul. 18, 2023 (CN) 202310880782.1

(51) Int. Cl. H01L 33/04; H01L 33/00; H01L 33/50; H01L 33/56

(52) U.S. Cl. CPC H01L 33/04; H01L 33/005; H01L 33/502; H01L 33/56; H01L 2933/0041; H01L 2933/005

(57) ABSTRACT

Disclosed are a light-emitting device with quantum dots and a manufacturing method thereof. The light-emitting device includes a light-emitting diode chip, a transparent barrier layer, a quantum dot film, and a transparent protective layer. The transparent barrier layer is disposed on the light-emitting diode chip. The quantum dot film is disposed on the transparent barrier layer, such that the light-emitting diode chip is separated from the quantum dot film by the transparent barrier layer. The transparent protective layer is disposed on the quantum dot film, such that the quantum dot film is encapsulated between the transparent barrier layer and the transparent protective layer.

### CROSS-REFERENCE TO RELATED APPLICATIONS

This non-provisional application claims priority claim under 35 U.S.C. § 119(a) on China Patent Application No. 202310880782.1 filed Jul. 18, 2023, the entire contents of which are hereby incorporated by reference.

### BACKGROUND

### Technical Field

This disclosure relates to a light-emitting device formed by light-emitting diodes, and in particular to a light-emitting device with quantum dots, and a manufacturing method thereof.

### Related Art

Quantum dots are excited by light to produce excitation light. Therefore, the quantum dots are often configured to convert a wavelength of a light-emitting diode, such that a light-emitting spectrum of a light-emitting device is not limited to the original light-emitting spectrum of the light-emitting diode, and the required light-emitting effect is achieved. Existing application of the quantum dots is to add semiconductor nanoparticles to a carrier base material, and the carrier base material is configured to directly cover a light-emitting diode chip with the carrier base material to form a quantum dot film. Light emitted by the light-emitting diode chip passes through the quantum dot film so as to excite the quantum dots to produce excitation light.

The above application causes two problems. The light-emitting diode chip generates heat when being energized to emit light, and the quantum dot film is in direct contact with the surface of the light-emitting diode chip, thereby easily leading to rapid deterioration of the carrier base material. The carrier base material is directly exposed to the air, and is contact in oxygen and water vapor in atmosphere, thereby easily leading to degradation and deterioration of the carrier base material. The two factors will lead to rapid deterioration of the quantum dot film, thereby affecting the service life of the light-emitting device with the light-emitting diode.

### SUMMARY

In view of the above technical problems, this disclosure provides a light-emitting device with quantum dots, and a manufacturing method thereof, thereby prolonging the life of a quantum dot film.

This disclosure provides a light-emitting device with quantum dots, including a light-emitting diode chip, a transparent barrier layer, a quantum dot film, and a transparent protective layer. The transparent barrier layer is disposed on the light-emitting diode chip. The quantum dot film is disposed on the transparent barrier layer, such that the light-emitting diode chip is separated from the quantum dot film by the transparent barrier layer. The transparent protective layer is disposed on the quantum dot film, such that the quantum dot film is encapsulated between the transparent barrier layer and the transparent protective layer.

In one or more embodiments, the light-emitting device with quantum dots further includes a base layer, configured to temporarily or permanently fix the light-emitting diode chip the base layer.

In one or more embodiments, a material of each of the transparent barrier layer, the quantum dot film and the transparent protective layer is a glue material capable of performing coating through dispensing and spray coating.

In one or more embodiments, the transparent protective layer has a multi-layer structure formed by different materials.

In one or more embodiments, the light-emitting device with quantum dots further includes a plurality of additional quantum dot films and a plurality of additional transparent protective layers, disposed above the transparent barrier layer, where each of the additional quantum dot films is encapsulated between two of the additional transparent protective layers.

This disclosure further provides a manufacturing method of a light-emitting device, including: providing a light-emitting diode chip; forming a transparent barrier layer disposed on the light-emitting diode chip; forming a quantum dot film disposed on the transparent barrier layer, such that the light-emitting diode chip is separated from the quantum dot film by the transparent barrier layer; and forming a transparent protective layer disposed on the quantum dot film, such that the quantum dot film is encapsulated between the transparent barrier layer and the transparent protective layer.

In one or more embodiments, the steps of forming the transparent barrier layer, the quantum dot film and the transparent protective layer include: sequentially injecting a glue material for forming the transparent barrier layer, the quantum dot film and the transparent protective layer into an accommodating space of a bracket, and curing the glue material to form the transparent barrier layer, the quantum dot film and the transparent protective layer.

In one or more embodiments, the steps of forming the transparent barrier layer, the quantum dot film and the transparent protective layer are to perform spray-coating, film-coating and molding processes sequentially to form each of the transparent barrier layer, the quantum dot film, and the transparent protective layer.

In one or more embodiments, the steps of forming the quantum dot film and forming the transparent protective layer are performed for plural times, such that a plurality of additional quantum dot films and are plurality of additional transparent protective layers are disposed on the transparent barrier layer, and each of the additional quantum dot films is encapsulated between two of the additional transparent protective layers.

In one or more embodiments, the manufacturing method of the light-emitting device further includes: cutting the transparent barrier layer, the quantum dot film, and the transparent protective layer to form a plurality of light-emitting devices respectively including a light-emitting diode chip.

According to the light-emitting device and the manufacturing method thereof provided by this disclosure, the quantum dot film is clamped and encapsulated between the transparent barrier layer and the transparent protective layer. The quantum dot film is not in direct contact with a high-temperature surface of the light-emitting diode chip, and is also isolated from the outside air. Therefore, the light-emitting device provided by this disclosure can effectively slow down the degradation of the material of the quantum dot film and prolong the life of the light-emitting device. Meanwhile, according to the manufacturing method provided by this disclosure, the light-emitting device can be produced in batches, and the required productivity can be maintained.

### BRIEF DESCRIPTION OF THE DRAWINGS

This disclosure will become more fully understood from the detailed description given herein below for illustration only, and thus not limitative of this disclosure, wherein:

FIG. 1 is a cross-sectional view of a light-emitting device with quantum dots according to a first embodiment of this disclosure.

FIG. 2 to FIG. 4 are cross-sectional views of a semi-finished product of a light-emitting device with quantum dots according to the first embodiment of this disclosure.

FIG. 5 is a cross-sectional view of a light-emitting device with quantum dots according to a variable example of the first embodiment of this disclosure.

FIG. 6 is a flowchart of a manufacturing method of a light-emitting device according to the first embodiment of this disclosure.

FIG. 7 is a cross-sectional view of a light-emitting device with quantum dots according to another variable example of the first embodiment of this disclosure.

FIG. 8 to FIG. 13 are cross-sectional views of a semi-finished product of a light-emitting device with quantum dots according to the second embodiment of this disclosure.

FIG. 14 is a cross-sectional view of a light-emitting device with quantum dots according to the second embodiment of this disclosure.

FIG. 15 is a flowchart of a manufacturing method of a light-emitting device according to the second embodiment of this disclosure.

### DETAILED DESCRIPTION

Referring to FIG. 1 to FIG. 4, disclosed by the first embodiment of this disclosure is a light-emitting device 100 with quantum dots, including a base layer 110, at least one light-emitting diode chip 120, a transparent barrier layer 130, a quantum dot film 140 and a transparent protective layer 150.

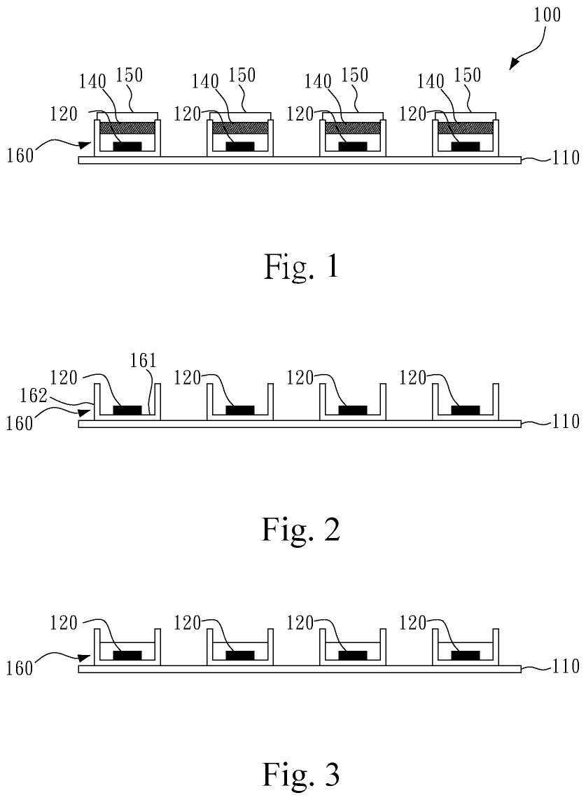

As shown in FIG. 1 and FIG. 2, specifically, the base layer 110 is configured to temporarily or permanently fix the light-emitting diode chip 120 on the base layer 110. For example, in a case that the base layer 110 is a release film, the light-emitting diode chip 120 is temporarily fixed on the base layer 110; and the light-emitting device 100 manufactured subsequently may be stripped from the base layer 110 to transfer to a backlight module substrate (such as PCB or glass) or other circuit substrates for die bonding/die mounting operation, for example, surface mounting and welding. In a case that the base layer 110 is a backlight module substrate or a circuit substrate, the light-emitting diode chip 120 is permanently fixed on the base layer 110 through the die bonding operation such as surface mounting and welding.

As shown in FIG. 1, the light-emitting diode chip 120 may be but not limited to a blue light LED. The quantum dot film 140 is a film containing light emitting semiconductor nanoparticles. These particles may be excited by light emitted by a light-emitting diode chip 120 and convert a wavelength of the light emitted by the light-emitting diode chip 120, such that the light-emitting wavelength finally emitted by the light-emitting device 100 conforms to an expected spectrum. For example, the light finally emitted by the light-emitting device 100 may be converted and adjusted into white light.

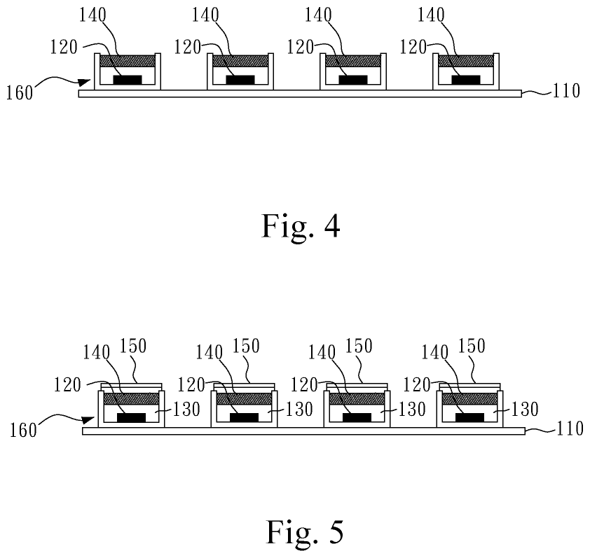

As shown in FIG. 1, FIG. 3 and FIG. 4, the transparent barrier layer 130 is disposed on the light-emitting diode chip 120, and the quantum dot film 140 is disposed on the transparent barrier layer 130, such that the light-emitting diode chip 120 and the quantum dot film 140 are separated by the transparent barrier layer 130.

Therefore, in a case that the light-emitting diode chip 120 is energized to emit light, high temperature of the light-emitting diode chip 120 will not directly affect the quantum dot film 140. Specifically, a thickness of the quantum dot film 140 is between 20 μm and 200 μm, and a material of the quantum dot film may be a glue material that can be coated through dispensing or spray coating, such as photo-hardening adhesive mixed nanoparticles. A thickness of the transparent barrier layer 130 is between 20 μm and 200 μm, a material of the transparent barrier layer may be a glue material that can be coated through dispensing or spray coating, such as photo-hardening adhesive, and the transparent barrier layer 130 has low thermal conduction coefficient. The transparent barrier layer 130 may form a high temperature difference between an upper surface of the light-emitting diode chip 120 and a lower surface of the quantum dot film 140, thereby preventing the lower surface of the quantum dot film 140 from directly bearing the high temperature of the light-emitting diode chip 120 and slowing down the degradation of the quantum dot film 140 due to heating.

As shown in FIG. 1, the transparent protective layer 150 is disposed on the quantum dot film 140, such that the quantum dot film 140 is encapsulated between the transparent barrier layer 130 and the transparent protective layer 150 to form a sandwich interlayer structure. The transparent protective layer 150 further isolates the quantum dot film 140 from being in contact with the outside air, thereby preventing the degradation of the quantum dot film 140 due to water or oxygen in the air.

Specifically, a material of the transparent protective layer 150 may be a pure organic material, for example, PE, or is a glue material that can perform rapid coating through dispensing or spray coating, with a thickness between 20 μm and 200 μm. Nano-scale inorganic powder may be further mixed in the organic material of the transparent protective layer 150, for example, SiO2, TiO2 or Al2O3, thereby improving the rigidity and gas barrier property of the transparent protective layer 150, and adjusting the optical characteristic of the transparent protective layer 150. In addition, the transparent protective layer 150 may be a coating film made of an inorganic material, for example, for example, Al2O3 film formed through atomic layer deposition (ALD), with a thickness between 10 nm and 500 nm. Specifically, the transparent protective layer 150 is suitable for coating and covering the quantum dot film 140 to isolate the quantum dot film 140 from being in contact with the outside air; therefore, the material or setting manner of the transparent protective layer 150 is not limited, as long as the quantum dot film 140 can be isolated from being in contact with the outside air.

As shown in FIG. 5, in addition, the transparent protective layer 150 may have a multi-layer structure formed by different materials. For example, a first transparent protective layer made of the inorganic material is formed through dispensing, and then a second transparent barrier layer is formed on the first transparent protective layer through the Al2O3 coating film formed through ALD.

As shown in FIG. 1 and FIG. 2, the light-emitting device 100 of the first embodiment may further include a bracket 160. The bracket 160 may be made of an organic material, for example, epoxy resin, or may be made of a metal material. The bracket 160 includes a bottom part 161 and a side part 122 encircling to an edge of the bottom part 161. The side part 122 can surround the bottom part 161, such that an accommodating space is formed between the bottom part 161 and the side part 122. The bottom part 161 is configured to be disposed on the base layer 110, and the light-emitting diode chip 120 is fixed at the bottom part 161, such that the light-emitting diode chip 120 is fixed on the base layer 110 indirectly through the bracket 160. The transparent barrier layer 130, the quantum dot film 140 and the transparent protective layer 150 are sequentially disposed on the light-emitting diode chip 120 and located in the accommodating space of the bracket 160. The bottom part 161 and the side part 122 form a container shape with the accommodating space, so the transparent barrier layer 130, the quantum dot film 140 and the transparent protective layer 150 can be disposed in the accommodating space through dispensing operation. When the light-emitting device 100 is produced in batches, a plurality of brackets 160 may be disposed on one large base layer 110 in an array manner, and the dispensing operations to plural brackets 160 can be performed at the same time through a plurality of dispensing nozzles disposed in an array manner. Meanwhile, glue materials for forming the transparent barrier layer 130, the quantum dot film 140 and the transparent protective layer 150 are sequentially injected into the plurality of brackets 160, thereby achieving the batched production effect.

As shown in FIG. 1 to FIG. 6, based on the light-emitting device 100 with quantum dots, the first embodiment of this disclosure further provides a manufacturing method of a light-emitting device.

As shown in FIG. 2 to FIG. 6, the manufacturing method is to provide one or more light-emitting diode chips 120 are first and dispose the light-emitting diode chip 120 on the base layer 110, as shown in step S110.

Specifically, step S110 may be subdivided into a plurality of sub-steps. Firstly, one or more brackets 160 are provided, and the bracket 160 is disposed on the base layer 110, as shown in step S112. Then, the light-emitting diode chip 120 is fixed on a bottom part 161 of the bracket 160, as shown in step S114.

The order of step S112 and step S114 is not limited, as long as the light-emitting diode chip 120 can be disposed on the base layer 110 indirectly through the bracket 160. Therefore, in step S110, step S114 may be performed first. The light-emitting diode chip 120is fixed at the bottom part 161, and then step S112 is performed. The bracket 160 is disposed on the base layer 110.

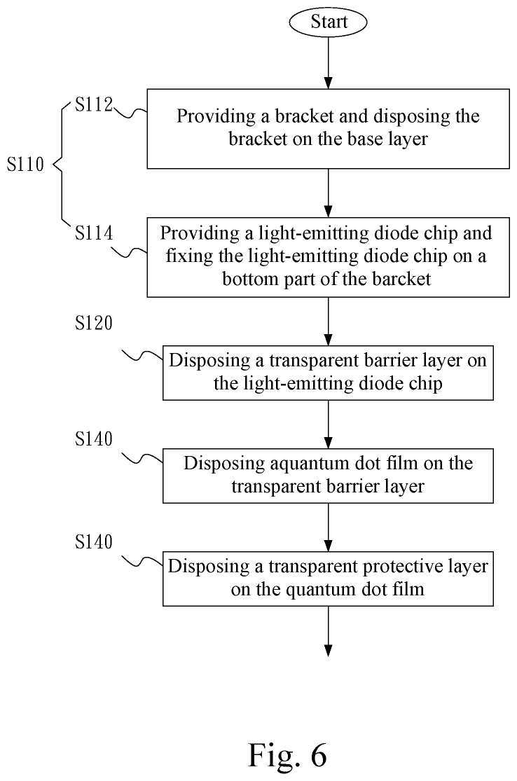

As shown in FIG. 3 and FIG. 6, then, the accommodating space of the bracket 160 is subjected to dispensing; that is the glue material for forming the transparent barrier layer 130 is injected into the v, and the glue material is cured to form the transparent barrier layer 130 disposed on the light-emitting diode chip 120, as shown in step S120.

As shown in FIG. 4 and FIG. 6, the accommodating space of the bracket 160 is subjected to dispensing, the glue material for forming the quantum dot film 140 is injected, and the glue material is cured to form the quantum dot film 140 disposed on the transparent barrier layer 130, as shown in step S130.

As shown in FIG. 1 and FIG. 6, finally, the accommodating space of the bracket 160 is subjected to dispensing, the glue material for forming the transparent protective layer 150 is injected, and the glue material is cured to form the transparent protective layer 150 disposed on the quantum dot film 140, such that the quantum dot film 140 is encapsulated between the transparent barrier layer 130 and the transparent protective layer 150, as shown in step S140.

As shown in FIG. 5, step S140 may be performed for plural times by using the same or different glue materials respectively to form the transparent protective layer 150 with a multi-layer structure.

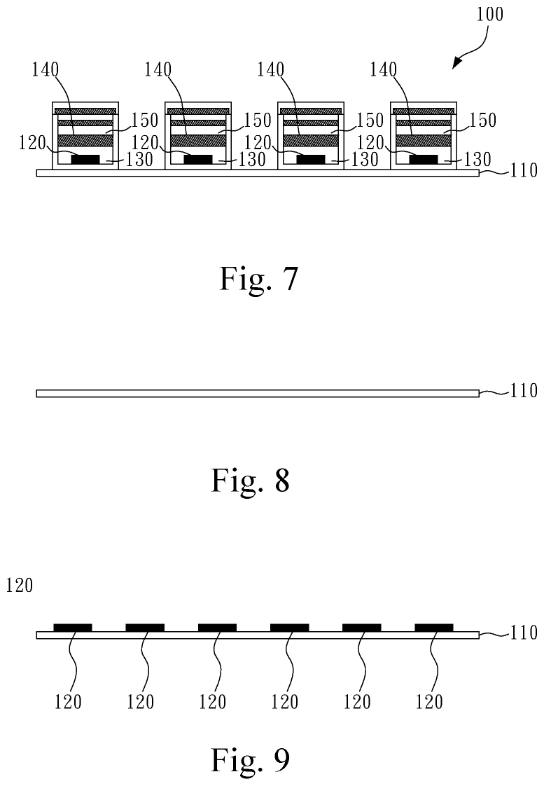

In addition, as shown in FIG. 7, step S130 and step 140 may be performed repeatedly for plural times, that is, the quantum dot film 140 is disposed on the transparent protective layer 150 repeatedly. And then the transparent protective layer 150 is disposed on the quantum dot film 140, such that a plurality of additional quantum dot films 140 and a plurality of additional transparent protective layers 150 are disposed above the transparent barrier layer 130. Further, each of the additional quantum dot film 140 is encapsulated between two of the additional transparent protective layers 150. Each of the additional quantum dot film 140 may be configured with different excitation light spectra, such that the spectrum finally emitted by the light-emitting device 100 conforms to the requirements.

Referring to FIG. 8 to FIG. 15, disclosed by the second embodiment of this disclosure are a light-emitting device 100 with quantum dots and a manufacturing method of the light-emitting device. According to the manufacturing method of the light-emitting device provided by the second embodiment, the bracket 160 is omitted, and batched production is realized through a manner different from dispensing.

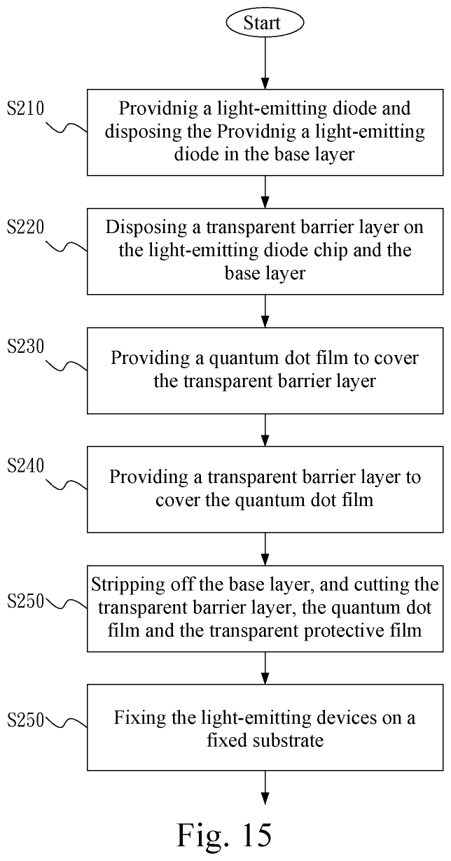

As shown in FIG. 8, FIG. 9 and FIG. 15, the manufacturing method includes: one or more light-emitting diode chips 120 are provided first, and the light-emitting diode chip 120 is disposed on the base layer 110, as shown in step S210. In this embodiment, the base layer 110 is a release film, and the base layer 110 is stripped off in the subsequent step. The plurality of light-emitting diode chips 120 may be disposed on the base layer 110 through a pick and place process (P&P).

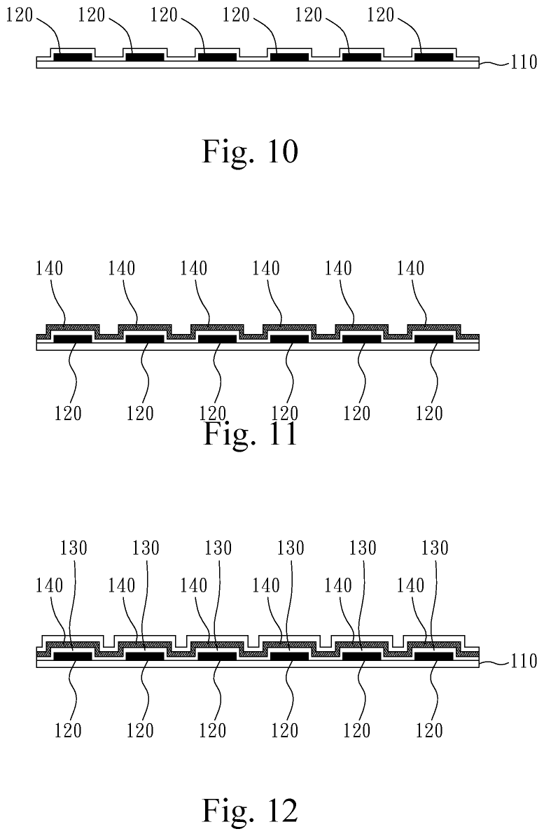

As shown in FIG. 10 and FIG. 15, then, an upper surface of the base layer 110 is subjected to processes such as spray coating, film coating or molding, such that the transparent barrier layer 130 is disposed on the light-emitting diode chip 120 and the base layer 110, as shown in step S220.

As shown in FIG. 11 and FIG. 15, further, the transparent barrier layer 130 is subjected to processes such as spray coating, film coating or molding, such that the quantum dot film 140 covers the transparent barrier layer 130, as shown in step S230.

As shown in FIG. 12 and FIG. 15, the quantum dot film 140 is subjected to processes such as spray coating, film coating or molding, such that the transparent barrier layer 150 covers the quantum dot film 140, as shown in step S240.

Like the first embodiment, step S240 may be performed for plural times by using the same or different glue materials respectively to perform processes such as spray coating, film coating or molding so as to form the transparent protective layer 150 with a multi-layer structure. Or in addition, step S230 and step 240 may be performed circularly for plural times, such that a plurality of additional quantum dot films 140 and a plurality of additional transparent protective layers 150 are disposed above the transparent barrier layer 130.

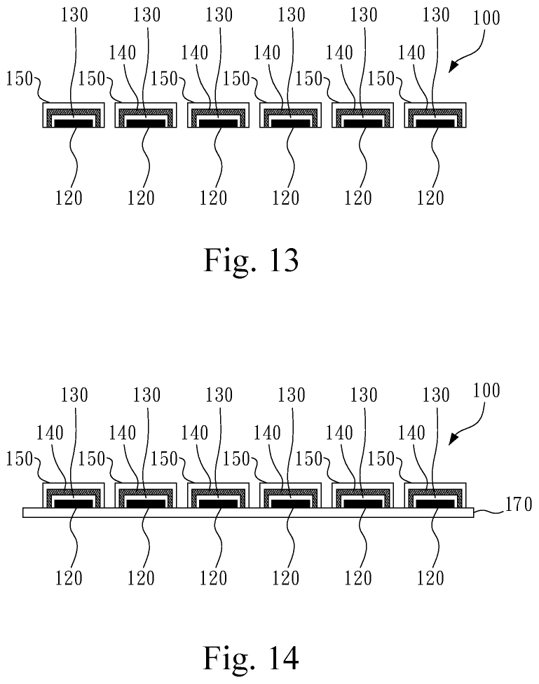

As shown in FIG. 13 and FIG. 15, then, the base layer 110 is stripped, and the transparent barrier layer 130, the quantum dot film 140 and the transparent protective film 150 are cut to form a plurality of light-emitting devices 100 respectively including a light-emitting diode chip 120, as shown in step S250. The cutting process may be water jet cutting or laser cutting.

As shown in FIG. 14 and FIG. 15, finally, the pick and place process (P&P) is performed, and fixing the plurality of light-emitting devices 100 on a fixing substrate 170, for example, a backlight module substrate, to form a light-emitting module with the plurality of light-emitting devices 100, as shown in step S260.

According to the light-emitting device 100 and the manufacturing method thereof provided by this disclosure, the quantum dot film 140 is clamped and encapsulated between the transparent barrier layer 130 and the transparent protective layer 150. The quantum dot film 140 is not in direct contact with a high-temperature surface of the light-emitting diode chip 120 and is also isolated from the outside air. Therefore, the light-emitting device 100 provided by this disclosure can effectively slow down the degradation of the material of the quantum dot film 140 and prolong the life of the light-emitting device 100. Meanwhile, according to the manufacturing method provided by this disclosure, the light-emitting device 100 can be produced in batches, and the required productivity can be maintained.

What is claimed is:

1. A light-emitting device with quantum dots, comprising:
a light-emitting diode chip;
a transparent barrier layer, disposed on the light-emitting diode chip;
a quantum dot film, disposed on the transparent barrier layer, such that the light-emitting diode chip is separated from the quantum dot film by the transparent barrier layer; and
a transparent protective layer, disposed on the quantum dot film, such that the quantum dot film is encapsulated between the transparent barrier layer and the transparent protective layer.

2. The light-emitting device with quantum dots according to claim 1, further comprising a base layer, configured to temporarily or permanently fix the light-emitting diode chip on the base layer.

3. The light-emitting device with quantum dots according to claim 1, wherein a material of each of the transparent barrier layer, the quantum dot film and the transparent protective layer is a glue material capable of performing coating through dispensing and spray coating.

4. The light-emitting device with quantum dots according to claim 1, wherein a material of the transparent protective layer is a coating film made of an inorganic material.

5. The light-emitting device with quantum dots according to claim 1, wherein the transparent protective layer has a multi-layer structure formed by different materials.

6. The light-emitting device with quantum dots according to claim 1, further comprising a bracket comprising a bottom part and a side part encircling to an edge of the bottom part, wherein an accommodating space is formed between the bottom part and the side part, and the light-emitting diode chip is fixed at the bottom part; and the transparent barrier layer, the quantum dot film and the transparent protective layer are sequentially disposed on the light-emitting diode chip and located at the accommodating space.

7. The light-emitting device with quantum dots according to claim 1, further comprising a plurality of additional quantum dot films and a plurality of additional transparent protective layers, disposed above the transparent barrier layer, wherein each of the additional quantum dot films is encapsulated between two of the additional transparent protective layers.

8. A manufacturing method of a light-emitting device, comprising:
providing a light-emitting diode chip;
forming a transparent barrier layer disposed on the light-emitting diode chip;
forming a quantum dot film disposed on the transparent barrier layer, such that the light-emitting diode chip is separated from the quantum dot film by the transparent barrier layer; and
forming a transparent protective layer disposed on the quantum dot film, such that the quantum dot film is encapsulated between the transparent barrier layer and the transparent protective layer.

9. The manufacturing method of a light-emitting device according to claim 8, further comprising: disposing the light-emitting diode chip on a base layer.

10. The manufacturing method of a light-emitting device according to claim 8, further comprising:
providing a bracket and disposing the bracket on the base layer; and fixing the light-emitting diode chip at a bottom part of the bracket.

11. The manufacturing method of a light-emitting device according to claim 10, wherein the step of forming the transparent barrier layer comprises:
injecting a glue material for forming transparent barrier layer into an accommodating space of the bracket; and
curing the glue material to form the transparent barrier layer.

12. The manufacturing method of a light-emitting device according to claim 10, wherein the step of forming the quantum dot film comprises:
injecting a glue material for forming the quantum dot film into an accommodating space of the bracket; and
curing the glue material to form the quantum dot film.

13. The manufacturing method of a light-emitting device according to claim 10, wherein the step of forming the transparent protective layer comprises:
injecting a glue material for forming transparent protective layer into an accommodating space of the bracket;
and curing the glue material to form the transparent protective layer.

14. The manufacturing method of a light-emitting device according to claim 13, wherein the step of forming the transparent protective layer is performed for plural times by using the same or different glue materials respectively, such that the transparent protective layer has a multi-layer structure.

15. The manufacturing method of a light-emitting device according to claim 8, wherein the steps of forming the transparent barrier layer, the quantum dot film and the transparent protective layer are to perform spray-coating, film-coating and molding processes sequentially to form each of the transparent barrier layer, the quantum dot film and the transparent protective layer.

16. The manufacturing method of a light-emitting device according to claim 8, wherein the steps of forming the quantum dot film and forming the transparent protective layer are performed for plural times, such that a plurality of additional quantum dot films and a plurality of additional transparent protective layers are disposed on the transparent barrier layer, and each of the additional quantum dot films is encapsulated between two of the additional transparent protective layers.

17. The manufacturing method of a light-emitting device according to claim 8, further comprising: cutting the transparent barrier layer, the quantum dot film, and the transparent protective layer to form a plurality of light-emitting devices respectively comprising a light-emitting diode chip.
